(19) United States
(12) Patent Application Publication
(10) Pub. No.: US 2021/0360748 A1
(43) Pub. Date: Nov. 18, 2021

(54) PLATE TYPE HEATER AND MANUFACTURING METHOD THEREOF

(71) Applicant: KSM COMPONENT CO., LTD., Gimpo-si (KR)

(72) Inventor: Joo Hwan Kim, Incheon (KR)

(73) Assignee: KSM COMPONENT CO., LTD., Gimpo-si (KR)

(21) Appl. No.: 17/318,378

(22) Filed: May 12, 2021

(30) Foreign Application Priority Data
May 14, 2020 (KR) 10-2020-0057932

(51) Int. Cl. H05B 3/26; H01L 21/67; H05B 1/02; C23C 16/46; C23C 14/22

(52) U.S. Cl. CPC H05B 3/265; H01L 21/67103; H05B 1/0233; H05B 2203/004; C23C 14/22; H05B 2203/005; H05B 2203/016; C23C 16/46

(57) ABSTRACT

Provided are a plate type heater and a vapor deposition apparatus including the same including: a ceramic plate substrate; a heating wire layer located on the inside or on an upper surface of the ceramic plate substrate; a power supply line; and a bridge located on the heating wire layer and connecting the heating wire and the power supply line, wherein the bridge connects the heating wire and the power supply line by curving a bridge material having a length of 1.2 to 5 times based on the shortest distance between the heating wire and the power supply line.

### CROSS-REFERENCE TO RELATED APPLICATION

This application claims under 35 U.S.C. § 119(a) the benefit of Korean Patent Application No. 10-2020-0057932 filed on 14 May 2020, the entire contents of which are incorporated herein by reference.

### BACKGROUND

### Technical Field

The present invention relates to a plate type heater and a manufacturing method thereof.

### Background Art

As a method of depositing a thin film of a predetermined thickness on a wafer such as a semiconductor substrate or glass, there are physical vapor deposition (PVD) using physical collision such as sputtering, chemical vapor deposition (CVD) using chemical reaction, etc.

A heater for heating the wafer is provided below a susceptor of a deposition apparatus for deposition as described above. As the heater, a plate type heater such as a ceramic heater is generally used. The plate type heater heats an object to be heated such as a wafer on a plate substrate by bending or curving a heating wire heated by receiving power to be disposed on the plate substrate and supplying power.

The temperature of the wafer is one of important causes of affecting the quality of the thin film, and it is important to accurately heat the temperature of the wafer and keep the temperature uniform. In particular, as the wafer size gradually increases, it is difficult to uniformly heat the wafer. Therefore, the function of uniformly heating a large-sized wafer is very importantly required in the plate type heater.

However, in the case of a conventional heater, there is a problem that heat is not uniformly distributed and is concentrated in a middle portion of a hot plate, resulting in a temperature deviation from an outer portion. In addition, due to this, there is a problem in that the hot plate is cracked due to a temperature difference between the hot plate, particularly the middle portion of the hot plate and the outer portion of the hot plate in the process of heating by supplying power or cooling by cutting off the power. In addition, the temperature difference as described above makes it difficult to uniformly heat the object to be heated, resulting in product defects such as wafers and a decrease in yield.

In order to solve the above problem, the plate type heater in the form shown in FIGS. 1 and 2 has been proposed. FIG. 1 is a cross-sectional view illustrating an example of a plate type heater in the related art, and FIG. 2 is a plan view illustrating an upper surface of the heater. In FIG. 1, a plate substrate 1 is a plate-shaped substrate and disposed with a first heating wire 2 and a second heating wire 3 on the upper surface thereof, and a first line 4 and a second line 5 are inserted into the central portion of the plate substrate 1. In addition, as illustrated in FIG. 2, the first line 4 and the second line 5 are connected to the first heating wire 2 and the second heating wire 3, respectively, and at this time, these lines and heating wires are connected to each other through bridges 4-1 and 5-1.

The problem of the temperature difference was improved by the plate type heater having the above structure. However, according to studies of the present inventors, it is confirmed that such a structure causes a problem of deteriorating the durability of the plate type heater.

### PRIOR ART DOCUMENT

### Patent Document

Korean Patent No. 10-0836183

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

The present inventors have made many efforts to solve the above problems of the related art, found that a structure of a bridge connecting a power supply line and a heating wire was changed in a plate to effectively prevent the cracks and damage to a plate type heater, and completed the present invention.

Therefore, an object of the present invention is to provide a plate type heater capable of effectively preventing cracks and damage to a ceramic plate substrate.

In order to achieve the object, the present invention provides a plate type heater including: a ceramic plate substrate; a heating wire layer located on the inside or on an upper surface of the ceramic plate substrate; a power supply line; and a bridge located on the heating wire layer and connecting the heating wire and the power supply line, wherein the bridge connects the heating wire and the power supply line by curving a bridge material having a length of 1.2 to 5 times based on the shortest distance between the heating wire and the power supply line.

In one embodiment of the present invention, the bridge may be formed to be curved to have one or more troughs and one or more crests.

In one embodiment of the present invention, the bridge may be formed in a waveform in which troughs and crests are alternately arranged, and the amplitude may be formed to be 1.2 to 20 times larger than the width of the bridge material. The bridge material may use those known in the art without limitation, and, for example, a material that generates heat by supplying electricity may be used as the same material as the heating wire.

In one embodiment of the present invention, power supply lines of different poles may be connected to one end and the other end of the heating wire disposed on the heating wire layer.

In one embodiment of the present invention, the heating wire may be disposed in a ring shape around a power supply line fixing part of the plate substrate, and the bridge may connect the power supply line of the power supply line fixing part and the heating wire in the ring.

In one embodiment of the present invention, the ring shape may include two or more rings, wherein the ring may be formed in a concentric circle or concentric circle-like shape centered on the power supply line fixing part, and each ring may be electrically connected.

In one embodiment of the present invention, the ring shape may include two or more rings, wherein the ring may be formed in a concentric circle or concentric circle-like shape centered on the power supply line fixing part, and the two or more rings may be connected with different power supply lines by bridges to enable differential heat generation.

In one embodiment of the present invention, the power supply line fixing part may be located at the central portion of the plate substrate.

In one embodiment of the present invention, the heating wire may be formed in a ring shape in a zigzag curved state.

In one embodiment of the present invention, a cross-sectional area of the bridge may be 2 to 10 times larger than a cross-sectional area of the heating wire.

In one embodiment of the present invention, the plate type heater may be used for heating a wafer.

In addition, the present invention provides a vapor deposition apparatus including the plate type heater of the present invention.

According to the present invention, in the plate type heater, the structure of the bridge connecting the power supply line and the heating wire in the ceramic plate substrate is changed from a conventional straight line to a shape including curves to effectively prevent the cracks and damage to the ceramic plate substrate, thereby greatly improving the durability.

In addition, by improving the durability as described above, the degree of freedom is increased in the heating wire arrangement structure of the plate substrate, thereby improving the heating uniformity of an object to be heated such as a wafer.

It should be understood that the effects of the present invention are not limited to the effects described above, but include all effects that can be deduced from the detailed description of the present invention or configurations of the invention described in appended claims.

### BRIEF DESCRIPTION OF THE DRAWINGS

FIG. 1 is a cross-sectional view illustrating an example of a plate type heater in the related art.

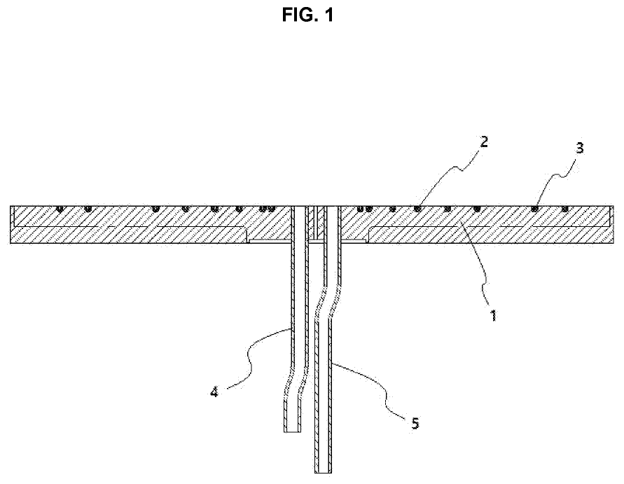

FIG. 2 is a plan view illustrating an upper surface of the plate type heater in the related art.

FIG. 3 is a cross-sectional view illustrating an embodiment of a plate type heater according to the present invention.

FIG. 4 is a plan view illustrating an upper surface of the plate type heater according to the present invention.

FIG. 5 is a plan view schematically illustrating a comparison between shapes of bridges included in the plate type heater in the related art and the plate type heater according to the present invention and a relation of a stress according thereto.

### DETAILED DESCRIPTION

Hereinafter, embodiments of the present invention will be described in detail with reference to the accompanying drawings so as to be easily implemented by those skilled in the art. However, the present invention may be implemented in various different forms and is not limited to the embodiments described herein. Throughout this specification, like elements designate like reference numerals.

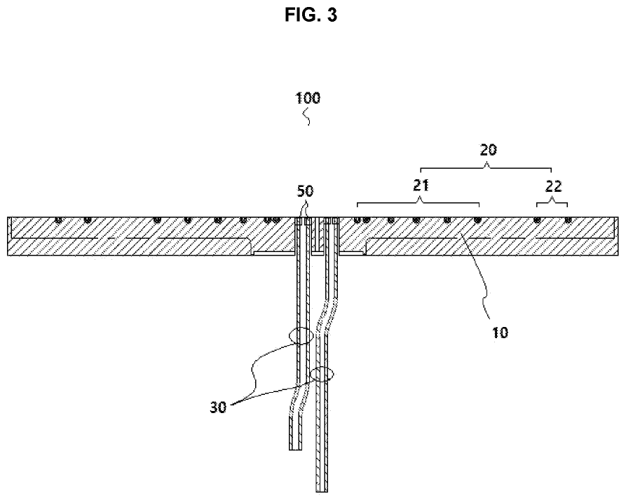

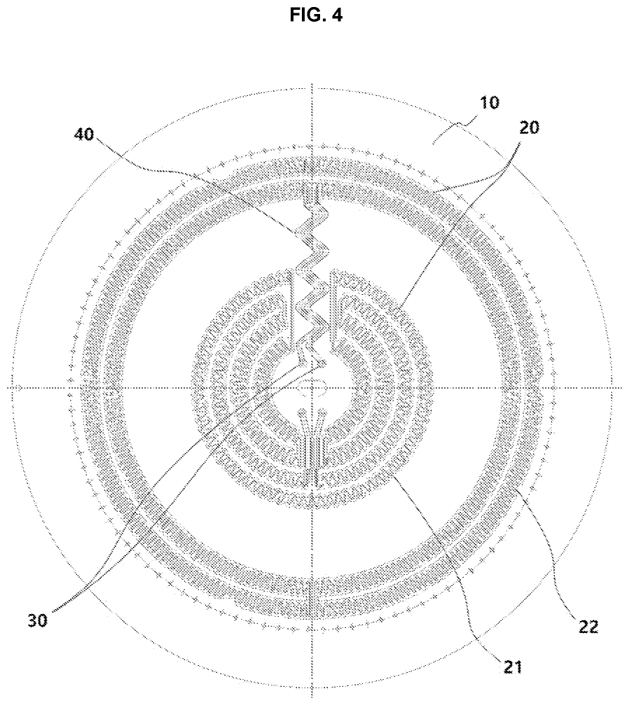

FIG. 3 is a cross-sectional view illustrating an embodiment of a plate type heater according to the present invention and FIG. 4 is a plan view illustrating an upper surface of the plate type heater according to the present invention. Referring to FIGS. 3 and 4, a plate type heater 100 of the present invention includes a ceramic plate substrate 10; a heating wire layer 20 located on the inside or on the upper surface of the ceramic plate substrate; a power supply line 30; and a bridge 40 located on the heating wire layer and connecting a heating wire and the power supply line.

The bridge 40 has a characteristic of connecting the heating wire and the power supply line by curving a bridge material having a length of 1.2 times to 5 times, based on the shortest distance between heating wires 21 and 22 and the power supply line 30. The length of the bridge material may be more preferably 1.5 to 3 times, and much more preferably 2 to 3 times. In the above, when the length of the bridge material is less than 1.2 times, it is difficult to disperse a stress generated in the bridge, and when the length exceeds 5 times, it is not preferable in that the degree of freedom of arranging the bridges and the heating wires decreases, and the installation process is inefficient.

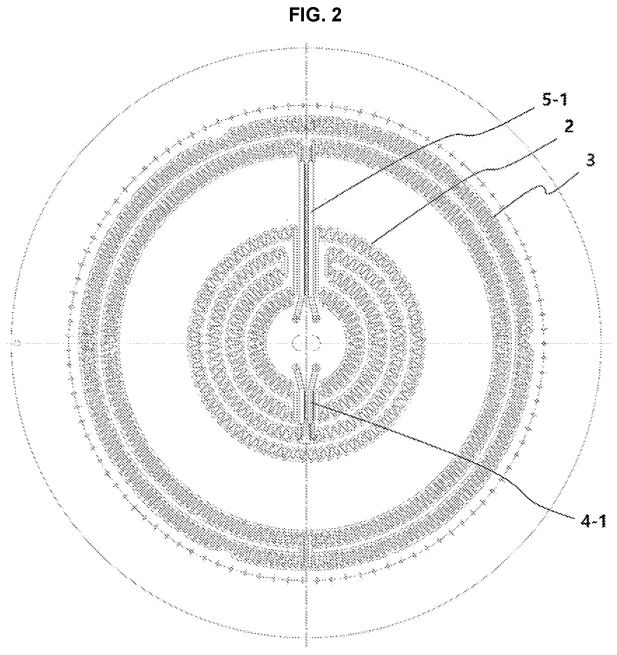

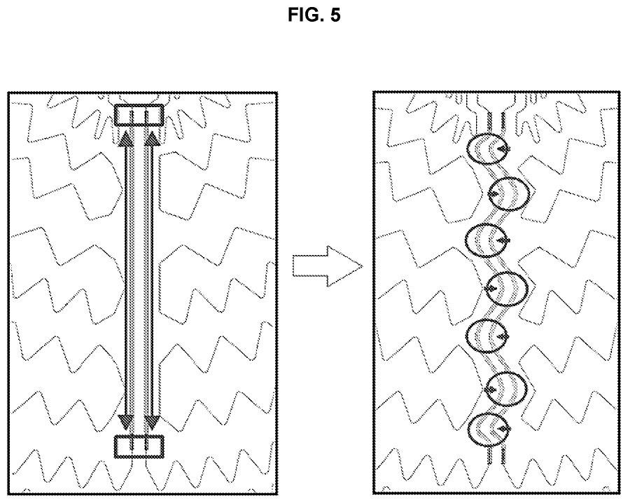

As illustrated in FIG. 2, in the case of a bridge formed in a straight line, when heat-treating at a high temperature during the manufacturing process, due to a difference in thermal expansion coefficient from the ceramic plate substrate (e.g., AlN thermal expansion coefficient forming the plate substrate: 4.4×10⁻⁶/K, Mo thermal expansion coefficient of a bridge material: 5.1×10⁻⁶/K), a stress occurs, and such a stress is concentrated to the end of the bridge, as illustrated in left panel of FIG. 5 to generate a large stress. Therefore, such a large stress causes cracks or large damage to the plate substrate 10.

Therefore, the present invention is characterized by providing the bridge 40 having a new structure to solve the above problems. That is, as illustrated in right panel of FIG. 5, when the bridge is formed to be curved in a waveform, the generated stress is distributed to a plurality of curved portions to effectively prevent cracks or damage to the plate substrate.

In particular, recently, the plate type heater in which the power supply line 30 at the central portion of the plate substrate 10 and the heating wire located outside the heating wire layer 20 are connected to each other by the bridge 40 has been widely used. In this type of plate type heater, the length of the bridge is inevitably lengthened, and as a large stress is concentrated at the end of the bridge, this cannot but to cause a problem of causing cracks or large damage to the plate substrate.

As such, as a plate type heater formed with a long bridge, for example, there is a plate type heater in which one heating wire is disposed on the plate substrate and the power supply line at the central portion and the heating wire located outside the heating wire layer are connected to each other by the bridge. In particular, recently, in order to reduce ununiform heating of the plate substrate and ununiform heating of the object to be heated such as a wafer, in many cases, separate heating wires are arranged in the central portion and the outer portion of the plate substrate. In this case, a bridge having a long length is required in order to connect the heating wire installed outside the plate substrate and the power supply line.

Therefore, the plate type heater of the present invention provides a technique capable of effectively solving the problem occurring in such a recent technical situation.

In addition, in the structure in which the separate heating wire is disposed as described above, a stronger current is applied to the heating wire disposed outside for uniform heating of the plate substrate, and in this case, the long length of the bridge makes the temperature around the bridge at the central portion higher than that of the other portion while passing through the central portion of the plate substrate. Accordingly, in order to solve this problem, a technique of forming a cross-sectional area of the bridge larger than a cross-sectional area of the heating wire has been used, and in such a bridge having a large cross-sectional area and a long length, a larger stress is intensively generated at the end of the bridge to more frequently cause cracks or large damage to the ceramic plate substrate. Therefore, the present invention may solve the problems at once to be very usefully used in the art.

In one embodiment of the present invention, the bridge 40 may be formed to be curved to have one or more troughs and one or more crests. As described above, the curved shape is not particularly limited, but a gently curved shape may be preferable for stress dispersion. The number of troughs and crests is not particularly limited, and may be formed in an appropriate number in consideration of the length of the bridge.

In addition, in an embodiment of the present invention, the bridge 40 may be formed in a waveform in which troughs and crests are alternately arranged, and the amplitude is 1.2 to 20 times, more preferably 2 to 10 times, much more preferably 3 to 5 times larger than the width of the bridge material.

If the amplitude is less than 1.2 times, a straight section of the bridge becomes longer, so that the effect of stress dispersion cannot be sufficiently obtained. If the amplitude exceeds 20 times, it is not preferable in that the degree of freedom of arranging bridges and heating wires decreases, and the installation process is inefficient.

In one embodiment of the present invention, power supply lines of different poles may be connected to one end and the other end of the heating wire disposed on the heating wire layer 20.

In an embodiment of the present invention, the heating wires 21 and 22 are disposed in a ring shape around a power supply line fixing part 50 of the plate substrate 10, and the bridge 40 may be a form of connecting the power supply line 30 of the power supply line fixing part and the hearing wire in the ring.

In an embodiment of the present invention, the ring shape includes two or more rings, and the ring is formed in a concentric circle or concentric circle-like shape centered on the power supply line fixing part, and each ring may be electrically connected.

In an embodiment of the present invention, the concentric circle or concentric circle-like shape means a concept including all shapes in which the ring shapes which are sequentially disposed are not in contact with each other.

In addition, in an embodiment of the present invention, the ring shape, as illustrated in FIG. 4, includes two or more rings, and the ring is formed in a concentric circle or concentric circle-like shape centered on the power supply line fixing part and the two or more rings may be connected with different power supply lines by bridges to enable differential heat generation.

In an embodiment of the present invention, the power supply line fixing part 50 may be located at the central portion of the plate substrate, but is not limited thereto. The location and shape of the power supply line fixing part may be applied with shapes known in the art without limitation.

In an embodiment of the present invention, as illustrated in FIG. 4, the heating wire may form a ring shape in a zigzag curved state. The zigzag curved shape may be applied with shapes known in the art without limitation.

In an embodiment of the present invention, the cross-sectional area of the bridge may be 2 to 10 times larger than the cross-sectional area of the heating wire. The reason for forming a large cross-sectional area of the bridge as described above is the same as described above.

In an embodiment of the present invention, the plate type heater may be used for heating a wafer, but is not limited thereto. That is, in addition to the heating of the wafer, the plate type heater may be used for heating all objects to be heated known in the art.

In addition, the present invention provides a vapor deposition apparatus including the plate type heater 100 of the present invention. The vapor deposition apparatus includes all vapor deposition apparatuses used for physical vapor deposition (PVD), chemical vapor deposition (CVD) using chemical reaction, or the like.

Regarding the structure of the vapor deposition apparatus, a structure known in the art may be applied without limitation to parts which are not described in the present invention.

While the preferred embodiment of the present invention has been described in detail, the scope of the present invention is not limited thereto, and various modifications and improvements of those skilled in the art using a basic concept of the present invention defined in the appended claims also belong to the scope of the present invention.

What is claimed is:

1. A plate type heater comprising:
a ceramic plate substrate;
a heating wire layer located on the inside or on an upper surface of the ceramic plate substrate;
a power supply line; and
a bridge located on the heating wire layer and connecting the heating wire and the power supply line,
wherein the bridge connects the heating wire and the power supply line by curving a bridge material having a length of 1.2 to 5 times based on the shortest distance between the heating wire and the power supply line.

2. The plate type heater of claim 1, wherein the bridge is formed to be curved to have one or more troughs and one or more crests.

3. The plate type heater of claim 2, wherein the bridge is formed in a waveform in which troughs and crests are alternately arranged, and an amplitude is formed to be 1.2 to 20 times larger than the width of the bridge material.

4. The plate type heater of claim 1, wherein power supply lines of different poles are connected to one end and the other end of the heating wire disposed on the heating wire layer.

5. The plate type heater of claim 1, wherein the heating wire is disposed in a ring shape around a power supply line fixing part of the plate substrate, and
the bridge connects the power supply line of the power supply line fixing part and the heating wire in the ring.

6. The plate type heater of claim 5, wherein the ring shape includes two or more rings, wherein the ring is formed in a concentric circle or concentric circle-like shape centered on the power supply line fixing part, and each ring is electrically connected.

7. The plate type heater of claim 5, wherein the ring shape includes two or more rings, wherein the ring is formed in a concentric circle or concentric circle-like shape centered on the power supply line fixing part, and the two or more rings are connected with different power supply lines by bridges to enable differential heat generation.

8. The plate type heater of claim 5, wherein the power supply line fixing part is located at the central portion of the plate substrate.

9. The plate type heater of claim 5, wherein the heating wire is formed in a ring shape in a zigzag curved state.

10. The plate type heater of claim 1, wherein a cross-sectional area of the bridge is 2 to 10 times larger than a cross-sectional area of the heating wire.

11. The plate type heater of claim 1, wherein the plate type heater is used for heating a wafer.

12. A vapor deposition apparatus comprising the plate type heater according to claim 1.
